(19) United States
(12) Patent Application Publication
(10) Pub. No.: US 2024/0274418 A1
(43) Pub. Date: Aug. 15, 2024

(54) PLASMA DENSITY MEASUREMENT SENSOR, APPARATUS FOR MEASURING REAL-TIME PLASMA DENSITY HAVING THE SAME, AND OPERATING METHOD THEREOF

(71) Applicant: Samsung Electronics Co., Ltd., Suwon-si (KR)

(72) Inventors: Sungho Jang, Suwon-si (KR); Protopopov Vladimir, Suwon-si (KR); Dohoon Kwon, Suwon-si (KR); Sangki Nam, Suwon-si (KR); Dougyong Sung, Suwon-si (KR); Sungwon Cho, Suwon-si (KR)

(21) Appl. No.: 18/455,949

(22) Filed: Aug. 25, 2023

(30) Foreign Application Priority Data
Feb. 13, 2023 (KR) 10-2023-0018697

(51) Int. Cl. H01J 37/32

(52) U.S. Cl. CPC H01J 37/32972; H01J 2237/24564

(57) ABSTRACT

An apparatus for measuring real-time plasma density includes, at least one plasma density measurement sensor in a process chamber, the at least one plasma density measurement sensor being configured to sense a plasma current between a first electrode and a second electrode when plasma is generated, and to generate an optical signal in response to the plasma current, and an optical signal detector on a side surface of the process chamber, the optical signal detector being configured to detect the optical signal from the at least one plasma density measurement sensor.

### CROSS-REFERENCE TO RELATED APPLICATION(S)

This application claims benefit of priority to Korean Patent Application No. 10-2023-0018697, filed on Feb. 13, 2023, in the Korean Intellectual Property Office, the disclosure of which is incorporated herein by reference in its entirety.

### BACKGROUND

The present disclosure relates to a plasma density measurement sensor, an apparatus for measuring real-time plasma density having the same, and an operating method thereof.

In general, plasma processing apparatuses are used in a semiconductor manufacturing process. As semiconductor devices become highly integrated, an aspect ratio of patterns is gradually increasing. In order to form a pattern with a high aspect ratio, a plasma processing apparatus for providing a process gas having a uniform plasma density has been required.

### SUMMARY

An aspect of the present disclosure is to provide a plasma density measurement sensor for measuring plasma density in real time, an apparatus for measuring real-time plasma density having the same, and an operating method thereof.

According to an aspect of the present disclosure, an apparatus for measuring real-time plasma density may include: at least one plasma density measurement sensor in a process chamber, the at least one plasma density measurement sensor being configured to sense a plasma current between a first electrode and a second electrode when plasma is generated and to generate an optical signal in response to the plasma current; and an optical signal detector on a side surface of the process chamber, the optical signal detector being configured to detect the optical signal from the at least one plasma density measurement sensor.

According to an aspect of the present disclosure, an operating method of an apparatus for measuring real-time plasma density may include: measuring a plasma current between a first electrode and a second electrode in a plasma density measurement sensor; generating an optical signal with an optical signal detector in response in response to the plasma current in the plasma density measurement sensor; receiving the optical signal from the optical signal detector; and calculating a plasma density corresponding to the received optical signal.

According to an aspect of the present disclosure, a plasma density measurement sensor may include: a first electrode extending from an upper portion of a substrate; a second electrode extending from an upper portion of the substrate; a battery in the substrate and connected between the first electrode and a ground terminal; a resistor in the substrate and connected between the second electrode and the ground terminal; and an optical signal generator configured to receive a control voltage of the second electrode and to generate an optical signal in response to the control voltage, wherein the control voltage is a voltage in response to a plasma current flowing through the first electrode and the second electrode.

Using a plasma density measurement sensor, an apparatus for measuring real-time plasma density having the same, and an operating method thereof according to an example embodiment of the present disclosure, an optical signal corresponding to a plasma current may be generated and the generated optical signal may be detected to measure a plasma density in real time.

Using a plasma density measurement sensor, an apparatus for measuring real-time plasma density having the same, and an operating method thereof according to an example embodiment of the present disclosure, a plasma density may be measured in real time to diagnose process abnormalities and use the diagnosis to measure plasma dispersion, thereby improving facility productivity or a yield.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a conceptual view illustrating an apparatus for measuring real-time plasma density according to an example embodiment of the present disclosure;

FIG. 2 is a view illustrating a plasma density measurement sensor according to an example embodiment of the present disclosure;

FIG. 3 is a view exemplarily illustrating a light intensity according to a control voltage u according to an example embodiment of the present disclosure;

FIG. 4 is a view exemplarily illustrating a plasma density measurement sensor according to another example embodiment of the present disclosure;

FIG. 5 is a view illustrating exemplarily an example embodiment of a plasma density measurement sensor according to an example embodiment of the present disclosure;

FIG. 6 is a flowchart exemplarily illustrating an operating method of an apparatus for measuring real-time plasma density according to an example embodiment of the present disclosure;

FIG. 7 is a view illustrating an example of measuring plasma density in real time using an apparatus for measuring real-time plasma density according to an example embodiment of the present disclosure;

FIG. 8 is a view exemplarily illustrating a plasma processing apparatus according to an example embodiment of the present disclosure; and

FIG. 9 is a view exemplarily illustrating a spectro-tomography plasma diagnosis apparatus according to an example embodiment of the present disclosure.

### DETAILED DESCRIPTION

Hereinafter, the example embodiments of the present disclosure will be described clearly and in detail so that those skilled in the art may easily implement the present disclosure using the accompanying drawings.

According to an example embodiment of the present disclosure, a plasma density measurement sensor, an apparatus equipped with the same for measuring real-time plasma density, and an operating method thereof, may generate an optical signal in response to a plasma current. The generated optical signal may then be detected to measure plasma density in real time. Furthermore, using the same plasma density measurement sensor and apparatus, plasma density may be measured in real time to diagnose process abnormalities. The resulting diagnosis may be used to measure plasma dispersion, thereby improving facility productivity and yield.

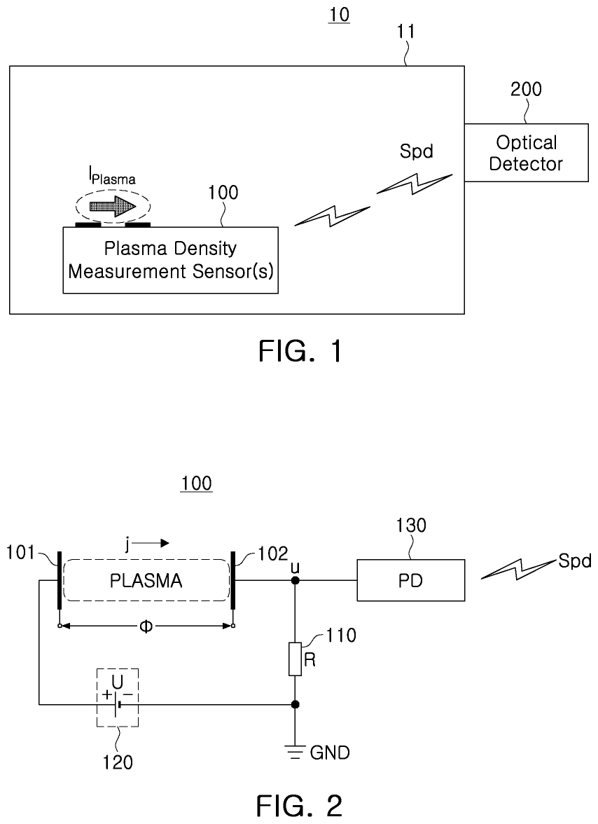

FIG. 1 is a conceptual view illustrating an apparatus 10 for measuring real-time plasma density according to an example embodiment of the present disclosure. Referring to FIG. 1, the apparatus 10 for measuring real-time plasma density may include at least one plasma density measurement sensor 100 and a photo or optical signal detector 200.

The plasma density measurement sensor 100 may be configured to detect a plasma current I_{Plasma} between electrodes when plasma is generated, and output an optical signal S_{pd} corresponding to the plasma current I_{Plasma}. In an example embodiment, at least one plasma density measurement sensor 100 may be inside a chamber 11. For example, the plasma density measurement sensor 100 may be on an internal wall of the chamber 11. Additionally, the plasma density measurement sensor 100 may be attached to a plurality of positions of a measurement sensor in the form of a wafer substrate. In this case, the plasma density measurement sensor 100 may be configured in a patch form.

Furthermore, the plasma density measurement sensor 100 may include a battery-based independent detection circuit. The plasma density measurement sensor 100 has electrodes spaced at specific intervals exposed to plasma. In an example embodiment, a size and interval of the electrodes may be appropriately adjusted according to a configuration of a device and a plasma environment. Here, the plasma current (I_{Plasma}) flowing by a voltage difference between the electrodes exposed to the plasma is affected by electrical characteristics of the plasma, and plasma state variables other than a plasma density may be extracted through electrical modeling of the plasma.

Furthermore, the plasma density measurement sensor 100 may include an optical signal conversion circuit for converting a signal into an optical signal S_{pd} proportional to a measured plasma current I_{Plasma}. The optical signal conversion circuit may generate/output an optical signal S_{pd} corresponding or in response to the plasma current I_{Plasma} to the outside. In an example embodiment, the optical signal S_{pd} may be a radio frequency (RF) signal having a frequency between several Hz and several tens of Hz.

Furthermore, the plasma density measurement sensor 100 may be electrically independent by being optically connected to an external device, thereby avoiding external electrical interference. Here, the plasma current I_{Plasma} may be circulated only inside a configured closed circuit to minimize interference of plasma to be measured.

In addition, the plasma density measurement sensor 100 may be configured as a simple circuit and may eliminate a size restriction of a measurement apparatus. In an example embodiment, since the size of the plasma density measurement sensor 100 is determined by a battery and components, the miniaturization of the sensor may be easily achieved in proportion to the miniaturization of the components. Furthermore, the plasma density measurement sensor 100 may assign various modulation functions to the transmission/acquisition of the optical signal S_{pd} to order to advance the transmission of measurement information. Furthermore, the plasma density measurement sensor 100 may perform real-time measurement of temperature when an electrode in contact with the plasma includes a material having an electrical property that varies in proportion to temperature.

In addition, the plasma density measurement sensor 100 may be configured to improve a signal to noise ratio (SNR) and separate the optical signal S_{pd} transmitted use a plurality of sensors into several wavelengths. That is, the plasma density measurement sensor 100 may blink at a specific frequency or change a light intensity.

The optical signal detector 200, which is a light detecting device, may be configured to receive the optical signal S_{pd}. The optical signal detector 200 may measure the plasma density in real time by obtaining plasma information in real time. In an example embodiment, the optical signal detector 200 may be outside the chamber 11 and may use an optical emission spectroscopy (OES) for the purpose of end point detection (EPD).

A typical apparatus for measuring plasma density measures the plasma density from a relationship between a current flowing by an electric field of a probe in contact with the plasma and an applied voltage by positioning a probe at a measurement position in a chamber and applying voltage (10V to 100V) from the outside. The typical apparatus has limitations on the size of a target and gas that may be measured by a structure, a material, and a position of the probe required for measurement, and has limitations in use in an environment in which voltage application and current extraction affect plasma conditions.

On the other hand, the apparatus 10 according to the example embodiment of the present disclosure may be equipped with the plasma density measurement sensor 100 for converting the signal into the optical signal S_{pd} proportional to a battery-based plasma current I_{Plasma}, thus obtaining plasma density information in real time through an external optical signal detector 200. The apparatus 10 may perform real-time measurement of the plasma density.

FIG. 2 is a view illustrating a plasma density measurement sensor 100 according to an example embodiment of the present disclosure. Referring to FIG. 2, the plasma density measurement sensor 100 may include a first electrode 101, a second electrode 102, a resistor 110, a battery 120, and an optical signal generator 130 (PD).

A plasma current I_{Plasma} may flow between the first electrode 101 and the second electrode 102. In an example embodiment, the first electrode 101 and the second electrode 102 may be configured in a form extending from an upper portion of a substrate. In an example embodiment, the first electrode 101 and the second electrode 102 may include a material having an electrical property that varies in proportion to temperature.

The resistor 110 may be connected between an output terminal for outputting the control voltage u and a ground terminal GND. Here, the control voltage u is a voltage corresponding to the plasma current I_{Plasma}.

The battery 120 may be connected between the first electrode 101 and the ground terminal GND. The first electrode 101 may be a positive voltage terminal.

The optical signal generator 130 may be configured to receive the control voltage u and to generate and output the optical signal S_{pd} corresponding to the control voltage u. In an example embodiment, the optical signal generator 130 may include a photodiode. Here, the photodiode may be a blanked photodiode. In an example embodiment, the optical signal generator 130 may be on an upper portion of the substrate or may be inside the substrate.

Hereinafter, a relationship between the plasma current and the plasma density will be briefly described. Basically, an electrical equation satisfies the following equation.

$$u = j R \qquad Equation 1$$

$$U = φ + j R .$$

Here, u is a control voltage, j is a current, R is a scaling resistor, U is a battery voltage, and φ is a potential between the electrodes 101 and 102.

A single electron between the electrodes satisfies the following equation.

$$m \frac{{v}_{1}^{2}}{2} - m \frac{{v}_{2}^{2}}{2} = e φ \qquad Equation 2$$

$$mv Δ v = e φ$$

$$Δ v = {v}_{1} - {v}_{2}$$

$$v = \frac{{v}_{1} + {v}_{2}}{2}$$

Here, m is the mass of an electron, v is the velocity of an electron, e is an electron charge, v₁ is a velocity of a first electron, and v₂ is the velocity of a second electron. Then, a single ion between the electrodes 101 and 102 satisfies the following equation.

$$M \frac{{w}_{1}^{2}}{2} - M \frac{{w}_{2}^{2}}{2} = e φ \qquad Equation 3$$

Here, M is the mass of ions, w₁ is the velocity of a first ion, and w₂ is the velocity of a second ion. In this case, an electron current satisfies the following equation.

$$N e Δ v S = \frac{{e}^{2} φ N S}{mv} \qquad Equation 4$$

Here, N is the density of free charges, and S is an area of the electrodes 101 and 102. In this case, an ion current satisfies the following equation.

$$N e Δ w S = \frac{{e}^{2} φ N S}{M w} \qquad Equation 5$$

Accordingly, the total current j satisfies the following equation.

$$j = {e}^{2} φ N S ( \frac{1}{mv} + \frac{1}{M w} ) \qquad Equation 6$$

Accordingly, a battery voltage U and a potential φ may be expressed by the following equation.

$$U = φ + {Ne}^{2} S φ ( \frac{1}{mv} + \frac{1}{M w} ) \cdot R \qquad Equation 7$$

$$φ = \frac{U}{1 + {Ne}^{2} S R ( \frac{1}{mv} + \frac{1}{M w} )}$$

Accordingly, the total current j may be expressed by the following equation.

$$j = \frac{U}{\frac{1}{{Ne}^{2} S ( \frac{1}{mv} + \frac{1}{M w} )} + R} . \qquad Equation 8$$

Furthermore, the control voltage u may be expressed by the following equation.

$$u = \frac{U}{\frac{1}{{Ne}^{2} S R ( \frac{1}{mv} + \frac{1}{M w} )} + 1} . \qquad Equation 9$$

Furthermore, the luminance of the optical signal generator 130 may be expressed by the following equation.

$$I = F ( u ) \qquad Equation 10$$

Here, I is a light intensity, and F is a light intensity function.

FIG. 3 is a view exemplarily illustrating a light intensity according to a control voltage u according to an example embodiment of the present disclosure. Referring to FIG. 3, with an increase in the control voltage u, the light intensity I increases in proportion thereto.

The optical signal generator 130 illustrated in FIG. 2 uses a photodiode. The present disclosure will not be limited thereto. The optical signal generator 130 may be a light emitting diode (LED).

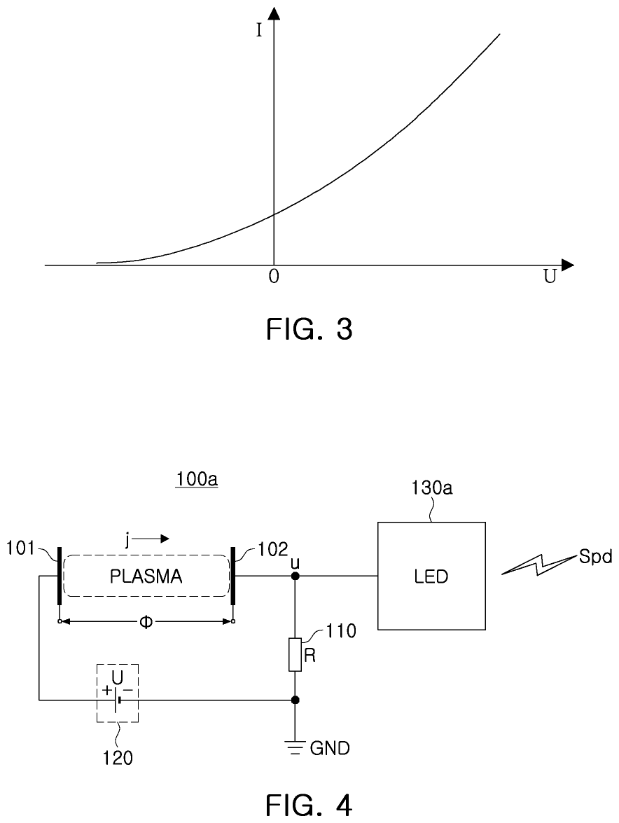

FIG. 4 is a view exemplarily illustrating a plasma density measurement sensor 100a according to another example embodiment of the present disclosure. Referring to FIG. 4, the plasma density measurement sensor 100a is equipped with an optical signal generator 130a with an LED as compared to the plasma density measurement sensor 100 illustrated in FIG. 2.

The plasma density measurement sensor according to an example embodiment of the present disclosure may be configured in a patch type.

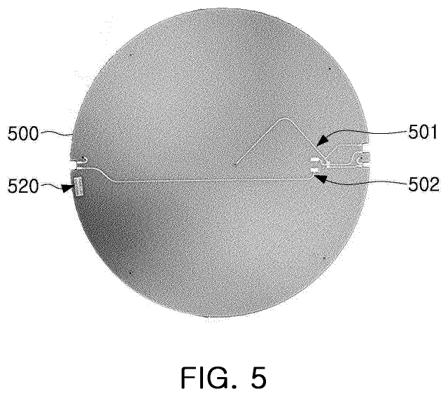

FIG. 5 is a view illustrating exemplarily an example embodiment of a plasma density measurement sensor 500 according to an example embodiment of the present disclosure. Referring to FIG. 5, the plasma density measurement sensor 500 may be a circular patch type. The plasma density measurement sensor 500 may include an optical signal generator 520 measuring a plasma current between electrodes 501 and 502 and outputting an optical signal in response to the measured plasma current. In an example embodiment, a thickness of the plasma density measurement sensor 500 may be 2 mm or less. In an example embodiment, a diameter of the plasma density measurement sensor 500 may be 1 mm or less. It should be understood that the thickness and diameter of the plasma density measurement sensor 500 are not limited thereto.

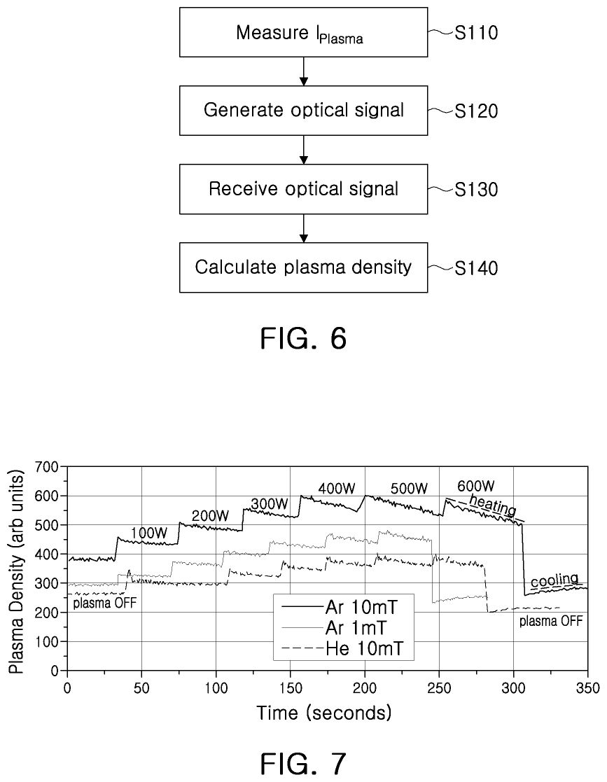

FIG. 6 is a flowchart exemplarily illustrating an operating method of an apparatus 10 for measuring real-time plasma density according to an example embodiment of the present disclosure. Referring to FIGS. 1 to 6, the apparatus 10 for measuring real-time plasma density may operate as follows.

Plasma may be generated in the chamber 11. The plasma density measurement sensor 100 may measure the plasma current I_{Plasma} between the electrodes 101 and 102 in real time (S110). The plasma density measurement sensor 100 may generate an optical signal S_{pd} in response to the plasma current I_{Plasma} (S120). The optical signal detector 200 on a side surface of the chamber 11 may receive the optical signal S_{pd} (S130). Then, the plasma density corresponding to the optical signal S_{pd} may be calculated (S140).

In an example embodiment, the control voltage corresponding to the optical signal may be generated in proportion to the plasma current I_{Plasma}. In an example embodiment, the plasma density measurement sensor 100 may divide the optical signal into a plurality of wavelengths, flash the optical signal at a predetermined frequency, or change an intensity of the optical signal. In an example embodiment, the plasma density measurement sensor 100 may modulate the optical signal, and the optical signal detector 200 may demodulate the modulated optical signal.

FIG. 7 is a view illustrating an example of measuring plasma density in real time using an apparatus 10 for measuring real-time plasma density according to an example embodiment of the present disclosure. Referring to FIG. 7, plasma densities of argon (Ar) and helium (He) may be measured in a plasma-on state in real time. Accordingly, plasma on/off operations may be controlled by measuring the plasma density in real time over time. As illustrated in FIG. 7, as real-time plasma density measurement can be performed, heating and cooling control are easily performed.

The apparatus 10 for measuring real-time plasma density according to an example embodiment of the present disclosure may be applied to a plasma processing apparatus.

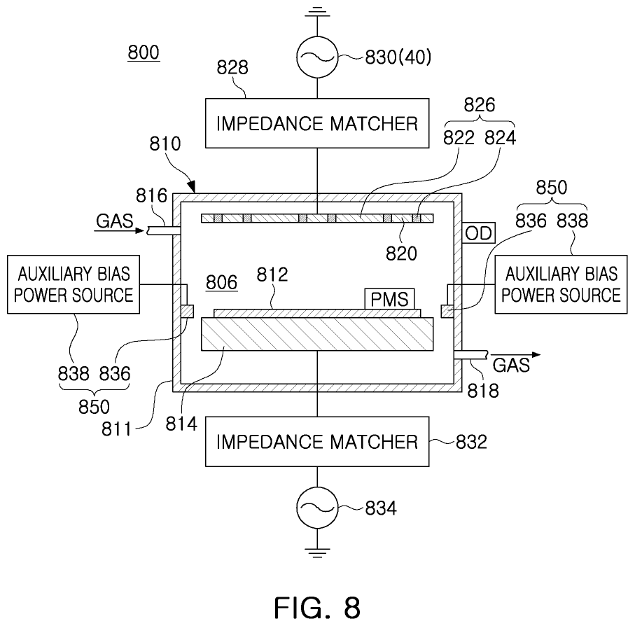

FIG. 8 is a view exemplarily illustrating a plasma processing apparatus 800 according to an example embodiment of the present disclosure. Referring to FIG. 8, the plasma processing apparatus 800 illustrates an inductively coupled plasma (ICP) etching or deposition apparatus.

The plasma processing apparatus 800 includes a gas injection portion 816 and a process chamber 810 having a gas discharge portion 818 installed therein. The process chamber 810 may have an internal space 806. The internal space 806 may be a plasma processing chamber. The process chamber 810 may be grounded. Process gas, such as etching gas or deposition gas, may be introduced into the process chamber 810 through the gas injection portion 816 and may be discharged to the outside through the gas discharge portion 818. The process chamber 810 may be maintained at a high vacuum in order to reduce or prevent process defects that may be caused by pollutants such as particles during a plasma reaction.

A high frequency electrode unit 826 and an electrostatic chuck 814 may be installed in the process chamber 810. The high frequency electrode unit 826 and the electrostatic chuck 814 may be used as a first electrode and a second electrode, respectively, and may be installed to face each other. The high frequency electrode unit 826 may be installed on a dielectric window 820 above the process chamber 810. The high frequency electrode unit 826 may include high frequency antennas 822 and 824.

The high frequency antennas 822 and 824 may include an internal antenna 822 corresponding to a central portion of a substrate 812 and an external antenna 824 outside the internal antenna 822 and corresponding to an edge of the substrate 812. The high frequency electrode unit 826 is connected to a high frequency power source 830 for applying high frequency power, that is, power of a radio frequency (RF), through an impedance matcher 828. The high frequency power applied through the high frequency power source 830 may be power having a frequency of 27 MHz or more. For example, the high frequency power applied through the high frequency power source 830 may be power having a frequency of 60 MHz. When the high frequency antennas 822 and 824 include the internal antenna 822 and the external antenna 824, a magnetic field may be more precisely controlled to uniformize the plasma density on the substrate 812.

A substrate 812, for example, a wafer, may be mounted on the electrostatic chuck 814. The wafer may be a wafer having a large diameter of 300 mm. The wafer may be a silicon wafer. A bias power source 834 for applying high frequency power through an impedance matcher 832 may be connected to the electrostatic chuck 814. The high frequency power applied through the bias power source 834 may be power having a frequency of 100 kHz to 10 MHz. For example, the high frequency power applied through the bias power source 834 may be power having a frequency of 2 MHz. Impedance matchers 828 and 832 may not be installed as necessary.

A process gas injected into the process chamber 810 may be converted into a plasma by a plasma applying portion 840. The plasma applying portion 840 may include a high frequency power source 830 electrically connected to the high frequency electrode unit 826. When the power is applied to the high frequency electrode unit 826 through the high frequency power source 830, the process gas injected into the process chamber 810 may be converted into a plasma. When high frequency or low-frequency power is applied to the electrostatic chuck 814 through the bias power source 834, the plasma generated in the process chamber 810 may be better directed toward the substrate 812.

The plasma processing apparatus 800 may have a plasma controller 850 installed around the electrostatic chuck 814. The plasma controller 850 may serve to control a plasma density on the substrate 812. The plasma density may influence the quality of etching uniformity or deposition uniformity of a film quality on the substrate 812. For example, when the plasma density on the substrate 812 does not become not uniform (e.g., remains uniform), an etching speed of a central portion of the substrate 812 may be different from an etching speed of the edge of the substrate 812.

The plasma controller 850 may include a body portion 836 around the electrostatic chuck 814 and an auxiliary bias power source 838 electrically connected to the body portion 836. The body portion 836 may be supported by an internal sidewall 811 of the process chamber 810. The body portion 836 may be formed in a cylindrical shape. The body portion 836 may have a ring shape. When the power, that is, a direct current voltage, is applied to a ferromagnetic core of the body portion 836 through the auxiliary bias power source 838, a magnetic field at a corner of the substrate 812 may be controlled. Accordingly, the plasma controller 850 may control the electric field of the edge of the substrate 812, thereby adjusting a difference in the plasma density between the center portion and the edge of the substrate 812. For example, the plasma controller 850 may make the plasma density on the substrate 812 uniform, thus making the etching speed of the central portion of the substrate 812 almost the same as the etching speed of the edge thereof.

As illustrated in FIG. 8, a plasma density measurement sensor (PMS) may be in the process chamber 810 and an optical signal detector (OD) may be on a side surface of the process chamber 810. Here, the plasma density measurement sensor (PMS) may be configured to generate an optical signal corresponding to the plasma current described in FIGS. 1 to 7. The optical signal detector OD may be configured to detect the optical signal. The plasma density may be measured in real time in response to the detected optical signal.

In some embodiments, the present disclosure is applicable to a spectro-tomography plasma diagnosis apparatus.

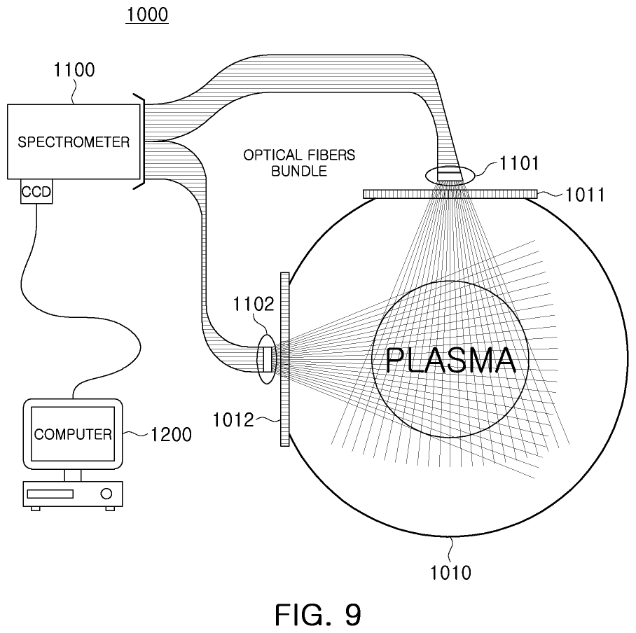

FIG. 9 is a view exemplarily illustrating the spectro-tomography plasma diagnosis apparatus according to an example embodiment of the present disclosure. Referring to FIG. 9, a spectro-tomography plasma diagnosis apparatus 1000 may include a plasma process chamber 1010, a spectrometer 1100, and a computing device 1200.

As illustrated in FIGS. 1 to 7, the plasma process chamber 1010 may be configured to measure the plasma current, generate the optical signal corresponding to the plasma current, and measure the plasma density corresponding to the detected optical signal in real time.

The spectrometer 1100 may be connected to first and second collimator and mechanical holders 1101 and 1102 through an optical channel. The first and second collimator and the mechanical holders 1101 and 1102 may be on windows 1011 and 1012 in different directions.

The computing device 1200 may be configured to analyze a distribution or a behavior of chemical species using spectrum data analyzed by the spectrometer 1100, or to calculate the plasma density or chamber temperature in real time using the optical signal detected by the spectrometer 1100. The spectrometer 1100 may be connected to the plasma process chamber 1010 through the optical channel. The spectrometer 1100 may be configured to analyze the chemical species and the behavior by performing a spectral analysis in real-time on each of the states of a multilevel pulse (or RF power) of the plasma process chamber 1010. For example, the spectrometer 1100 may be configured to synchronize to the multilevel pulse and analyze the spectrum according to each of the states through an image sensor (e.g., a CMOS image sensor, a CCD image sensor, or the like). Here, the states may correspond to a level of the multilevel pulse. Furthermore, the spectrometer 1100 may be configured to perform logarithmic transformation on an output signal of the image sensor. The spectrometer 1100 may include a synchronizer that may be configured to receive a trigger signal from the outside and synchronize control signals for controlling the spectrometer 1100 in response to the trigger signal.

The computing device 1200 may include at least one processor for driving/executing a program and a memory device for storing the program. The processor may perform a series of instructions to analyze a measured optical signal to calculate a corresponding plasma density, or to analyze the measured optical signal to calculate the plasma temperature. The memory may be configured to store a series of instructions that may be read by a computer. As the instructions stored in the memory are executed in the processor, the aforementioned operations may be performed. The memory may be a volatile memory or a nonvolatile memory. The memory may include a storage device to store user data.

The example embodiments described above may be implemented by hardware components, software components, and/or a combination of the hardware components and the software components. For example, the devices, methods, and components described in the example embodiment may be implemented using one or more general-purpose computers and special purpose computers such as a digitizer, for example, a processor, a controller, an arithmetic logic unit (ALU), a digital signal processor, a microcomputer, a field programmable gate array, a programmable logic unit (PLU), a microprocessor, or any other device that may execute and respond to instructions. A processing apparatus may perform an operating system (OS) and one or more software applications running on the OS.

Furthermore, the processing apparatus may access, store, manipulate, process, and generate data in response to the execution of the software. For convenience of understanding, one processing apparatus may be described as being used, but those skilled in the art in the corresponding technology field may understand that the processing apparatus may include a plurality of processing elements and/or multiple types of processing elements. For example, the processing apparatus may include a plurality of processors or one processor and one controller. Furthermore, other processing configurations (e.g., a co-processor configuration), such as parallel processors, are also possible.

Software may include a computer program, a code, an instruction, or combinations of one or more thereof, and may configure the processing apparatus to operate as desired or command the processing apparatus independently or collectively. The software and/or data may be permanently or temporarily embodied in any type of machine, component, physical device, virtual device, computer storage medium or device, or transmitted signal wave, in order to be interpreted by the processing apparatus or to provide an instruction or data to the processing apparatus. The software may be distributed on a network-connected computer system and stored or executed in a distributed manner. The software and data may be stored in one or more computer-readable recording media.

The present disclosure discloses a new measurement technology that can measure plasma state information of a plasma process facility in real time. In manufacturing a semiconductor, plasma facilities are used in a dry etch process and a CVD process, and the plasma state affects process performance and further product quality. However, there is a need for technology that may measure the plasma state in real time in semiconductor facilities. Accordingly, there is a need to develop a new plasma sensor technology that are accurate, realistic, and economical for use in the semiconductor facilities.

A measurement apparatus including a battery-based independent circuit according to an example embodiment of the present disclosure may transmit measured plasma information to the outside of the chamber through a light emitting circuit that is short-circuited by plasma between electrodes formed at specific intervals and operated by a current flowing in proportion to a plasma density (circuit plasma resistor). Such plasma information may be obtained through an optical measurement device outside the chamber. By optically performing the transmission of measurement information, a measurement circuit may be electrically disconnected from the outside, and an external optical signal acquisition device may use an optical emission spectroscopy (OES).

Existing plasma diagnostic technology is not suitable for real-time monitoring of semiconductor process facilities due to its principle and structure, and is primarily used during the development stage. In contrast, the plasma diagnostic technology of the present disclosure may be used to diagnose process abnormalities and measure plasma dispersion through real-time monitoring of plasma in semiconductor process facilities (e.g., Etch and CVD), thus improving both facility productivity and yield. When developing and introducing new facilities for next-generation devices, the plasma diagnostic technology of the present disclosure can be used as a means for verifying facility performance. Since this technology may minimize the size of a sensor, it can be integrated with MEMS technology to develop and utilize a micro sensor. The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. An apparatus for measuring real-time plasma density, comprising:
at least one plasma density measurement sensor in a process chamber, the at least one plasma density measurement sensor being configured to sense a plasma current between a first electrode and a second electrode when plasma is generated and to generate an optical signal in response to the plasma current; and
an optical signal detector on a side surface of the process chamber, the optical signal detector being configured to detect the optical signal from the at least one plasma density measurement sensor.

2. The apparatus of claim 1, wherein the first electrode and the second electrode comprise a material having an electrical property that varies in proportion to temperature.

3. The apparatus of claim 1, wherein the at least one plasma density measurement sensor is configured to circulate the plasma current into a closed circuit.

4. The apparatus of claim 1, wherein the at least one plasma density measurement sensor comprises:
a resistor connected between the second electrode and a ground terminal;
a battery connected between the first electrode and the ground terminal; and
an optical signal generator connected to the second electrode and configured to generate the optical signal in response to the plasma current flowing between the first electrode and the second electrode.

5. The apparatus of claim 4, wherein the optical signal generator includes at least one photodiode.

6. The apparatus of claim 4, wherein the optical signal generator includes at least one light emitting diode (LED).

7. The apparatus of claim 1, wherein the at least one plasma density measurement sensor is configured to divide the optical signal into a plurality of wavelengths, to flash the optical signal at a predetermined frequency, or to change an intensity of the optical signal in response to the plasma current.

8. The apparatus of claim 1, wherein the optical signal detector includes an optical emission spectroscopy.

9. The apparatus of claim 1, wherein the at least one plasma density measurement sensor is a circular patch form.

10. The apparatus of claim 1, further comprising:
a computing device configured to analyze the optical signal detected from the optical signal detector and to calculate a plasma density corresponding to the optical signal.

11. An apparatus for measuring real-time plasma density configured to include a plasma density measurement sensor performing an operating method, the method comprising:
measuring a plasma current between a first electrode and a second electrode in a plasma density measurement sensor;
generating an optical signal with an optical signal detector in response to the plasma current in the plasma density measurement sensor;
receiving the optical signal from the optical signal detector; and
calculating a plasma density in response to the optical signal.

12. The apparatus of claim 11, wherein a control voltage corresponding to the optical signal is generated in proportion to the plasma current.

13. The apparatus of claim 11, wherein the generating an optical signal comprises:
at least one of dividing the optical signal into a plurality of wavelengths; flashing the optical signal at a predetermined frequency; and changing an intensity of the optical signal.

14. The apparatus of claim 11, further comprising:
modulating the optical signal in the plasma density measurement sensor; and
demodulating the optical signal detected by the optical signal detector.

15. The apparatus of claim 11, wherein the first electrode and the second electrode comprise a material having an electrical property that varies in proportion to temperature, and calculating a temperature in response to the optical signal in real time.

16. A plasma density measurement sensor comprising:
a substrate;
a first electrode extending from an upper portion of the substrate;
a second electrode extending from the upper portion of the substrate;
a battery in the substrate and connected between the first electrode and a ground terminal;
a resistor in the substrate and connected between the second electrode and the ground terminal; and
an optical signal generator configured to receive a control voltage of the second electrode and to generate an optical signal in response to the control voltage,
wherein the control voltage is a voltage corresponding to a plasma current flowing through the first electrode and the second electrode.

17. The plasma density measurement sensor of claim 16, wherein the first electrode and the second electrode comprise a material having an electrical property that varies in proportion to temperature.

18. The plasma density measurement sensor of claim 16, wherein the optical signal generator is on the upper portion of the substrate.

19. The plasma density measurement sensor of claim 16, wherein the optical signal generator is in the substrate.

20. The plasma density measurement sensor of claim 16, wherein the optical signal generator comprises at least one photodiode or at least one light emitting diode (LED).
